(19) United States
(12) Patent Application Publication
(10) Pub. No.: US 2025/0294793 A1
(43) Pub. Date: Sep. 18, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventor: Tzu-Ging LIN, Kaohsiung City (TW)

(21) Appl. No.: 18/765,271

(22) Filed: Jul. 7, 2024

Related U.S. Application Data
(60) Provisional application No. 63/566,243, filed on Mar. 16, 2024.

(51) Int. Cl. H01L 29/775; H01L 27/092; H01L 29/423; H01L 29/66

(52) U.S. Cl. CPC H10D 30/43; H10D 30/014; H10D 64/021; H10D 84/853; H10D 30/6735

(57) ABSTRACT

Embodiments of the present disclosure provide semiconductor device structures and methods of forming the same. The structure includes a first source/drain region, a second source/drain region disposed adjacent the first source/drain region along a first direction, a third source/drain region disposed adjacent the first source/drain region along a second direction substantially perpendicular to the first direction, a first gate electrode layer disposed between the first source/drain region and the third source/drain region, a second gate electrode layer disposed adjacent the second source/drain region, and a first dielectric material disposed between the first and second gate electrode layers. The first dielectric material has a length less than or equal to a first distance between the first and second source/drain regions.

### CROSS-REFERENCE TO RELATED APPLICATIONS

This application claims priority to U.S. Provisional Application Ser. No. 63/566,243 filed on Mar. 16, 2024, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of various stages of manufacturing a semiconductor device structure, in accordance with some embodiments.

FIGS. 7A-10A are cross-sectional side views of various stages of manufacturing the semiconductor device structure taken along line A-A of FIG. 6, in accordance with some embodiments.

FIGS. 7B-10B are cross-sectional side views of various stages of manufacturing the semiconductor device structure taken along line B-B of FIG. 6, in accordance with some embodiments.

FIGS. 7C-10C are cross-sectional side views of various stages of manufacturing the semiconductor device structure taken along line C-C of FIG. 6, in accordance with some embodiments.

FIG. 11 is a top view of the semiconductor device structure shown in FIGS. 10A, 10B, 10C, in accordance with some embodiments.

FIGS. 12A-16A are cross-sectional side views of various stages of manufacturing the semiconductor device structure taken along line D-D of FIG. 11, in accordance with some embodiments.

FIGS. 12B-16B are cross-sectional side views of various stages of manufacturing the semiconductor device structure taken along line E-E of FIG. 11, in accordance with some embodiments.

FIG. 17 is a top view of the semiconductor device structure shown in FIGS. 16A and 16B, in accordance with some embodiments.

FIGS. 18A, 18B, 18C are various views of one of various stages of manufacturing the semiconductor device structure, in accordance with some embodiments.

FIG. 19 is a top view of the semiconductor device structure shown in FIGS. 18A, 18B, 18C, in accordance with some embodiments.

FIGS. 20A-24A are cross-sectional side views of various stages of manufacturing the semiconductor device structure taken along line F-F of FIG. 19, in accordance with some embodiments.

FIGS. 20B-24B are cross-sectional side views of various stages of manufacturing the semiconductor device structure taken along line G-G of FIG. 19, in accordance with some embodiments.

FIGS. 20C-24C are cross-sectional side views of various stages of manufacturing the semiconductor device structure taken along line H-H of FIG. 19, in accordance with some embodiments.

FIG. 22D is a top view of an opening in the semiconductor device structure, in accordance with some embodiments.

FIG. 25 is a top view of the semiconductor device structure shown in FIGS. 24A, 24B, and 24C, in accordance with some embodiments.

FIG. 26 is a top view of the semiconductor device structure, in accordance with alternative embodiments.

FIG. 27A-27C are top views of a dielectric material of the semiconductor device structure of FIG. 26, in accordance with some embodiments.

FIGS. 28A and 28B are cross-sectional side views of one of various stages of manufacturing the semiconductor device structure taken along line I-I of FIG. 26, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provide semiconductor device structures having a first dielectric material separating portions of a gate electrode layer and a second dielectric material to isolate active devices. In some embodiments, the first dielectric material has a first longitudinal axis, the second dielectric material has a second longitudinal axis, and the first longitudinal axis is substantially parallel to the second longitudinal axis. As a result, parasitic capacitance is reduced.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, FinFETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

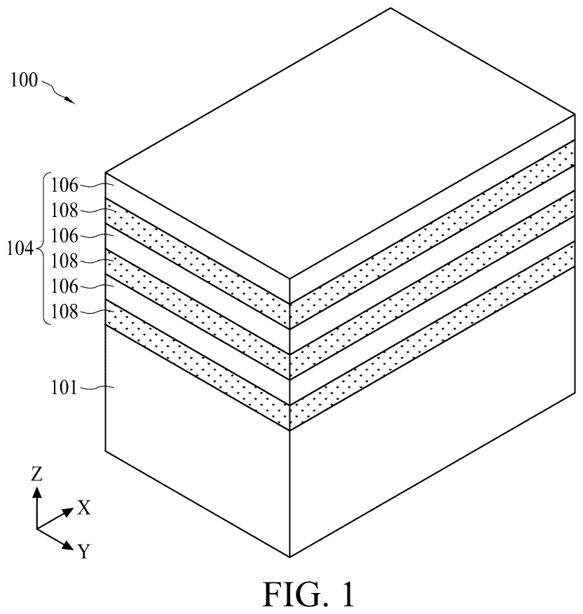

FIGS. 1-25 show exemplary processes for manufacturing a semiconductor device structure 100 according to embodiments of the present disclosure. It is understood that additional operations can be provided before, during, and after processes shown by FIGS. 1-25, and some of the operations described below can be replaced or eliminated, for additional embodiments of the method. The order of the operations/processes is not limiting and may be interchangeable.

FIGS. 1-6 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section clongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

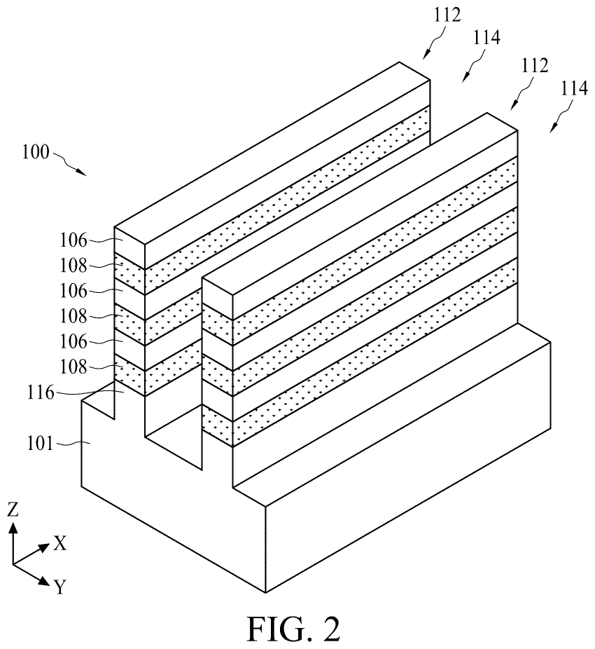

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking clement including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof. In some embodiments, each fin structure 112 has a longitudinal axis along the X direction.

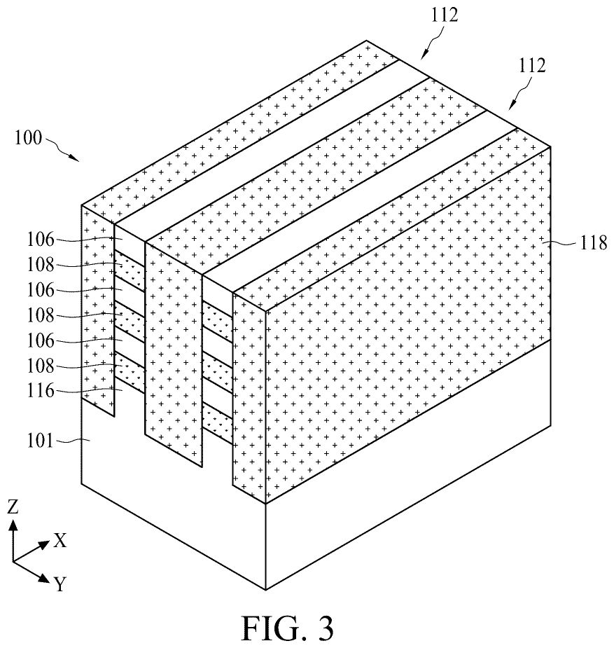

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

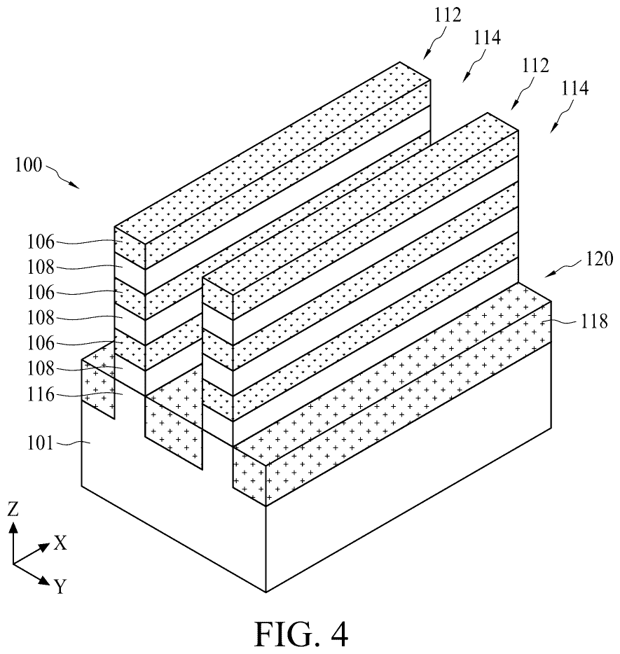

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101.

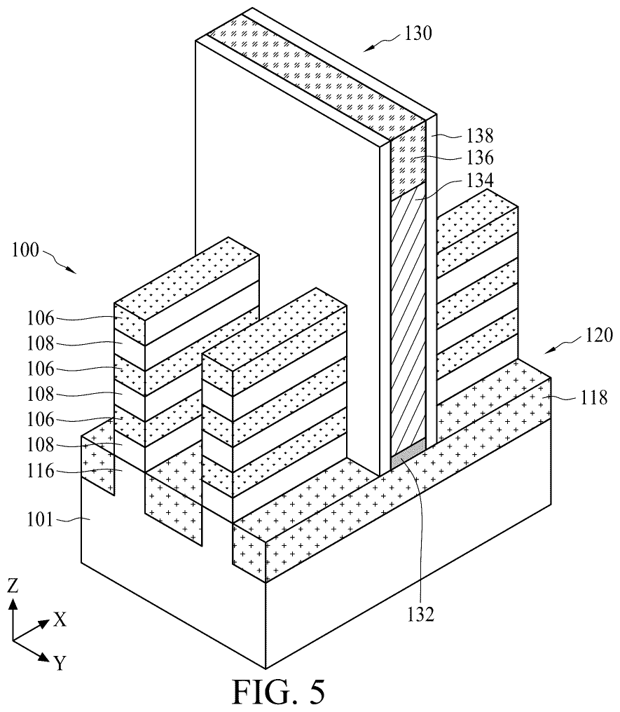

In FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. In some embodiments, the gate spacers 138 are also formed on the sidewalls of the exposed portions of the fin structures 112. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 of the sacrificial gate structure 130 serve as channel regions for the semiconductor device structure 100.

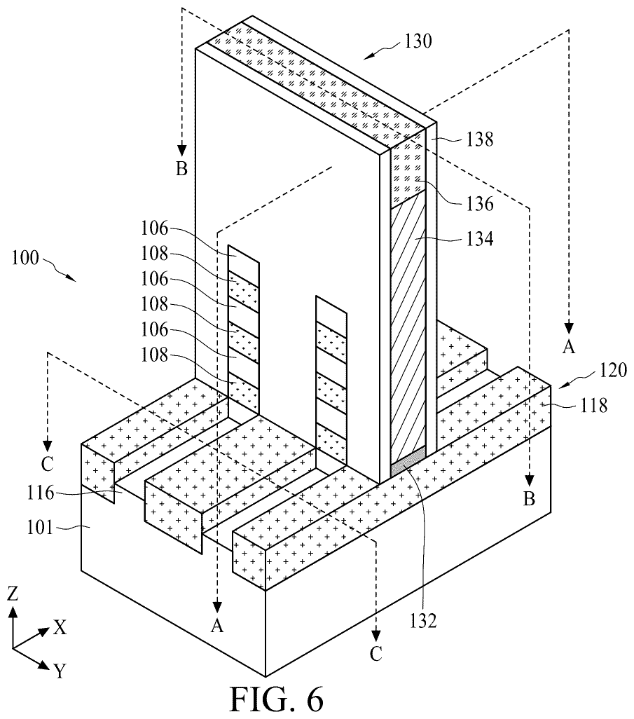

In FIG. 6, the portions of the fin structures 112 not covered by the sacrificial gate structure 130 and the gate spacers 138 are recessed to a level above, at, or below the top surfaces of the isolation regions 120. The recess of the portions of the fin structures 112 can be done by an etch process, either isotropic or anisotropic etch process, and the etch process may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant.

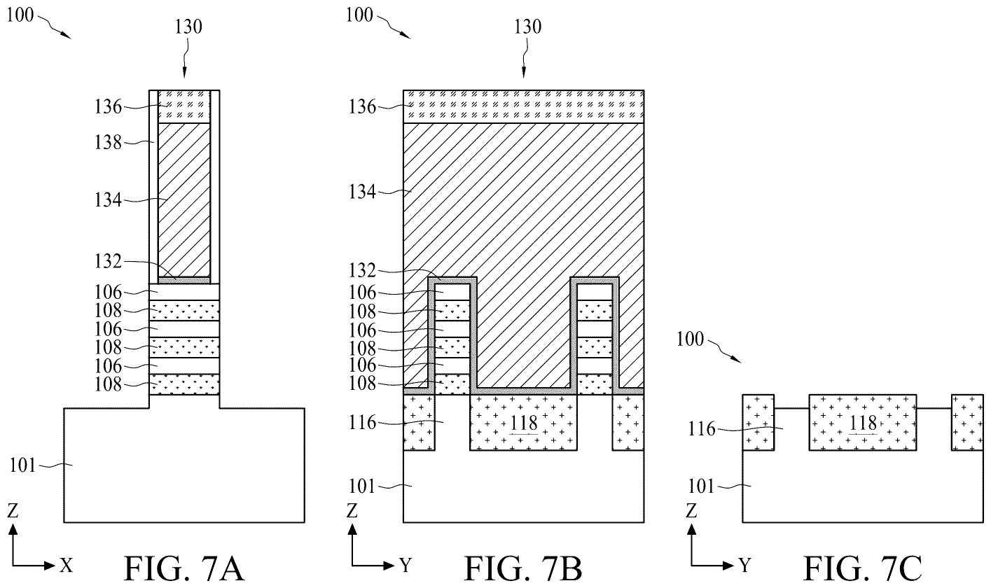

FIGS. 7A, 7B, and 7C are cross-sectional side views of the semiconductor device structure 100 taken along line A-A, line B-B, and line C-C of FIG. 6, respectively.

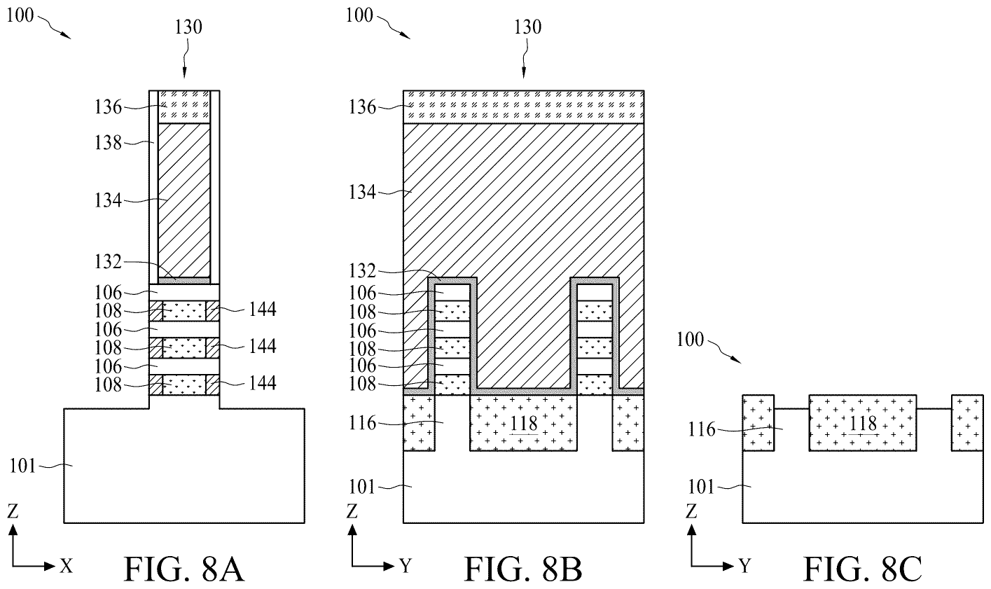

FIGS. 8A, 8B, and 8C are cross-sectional side views of one of various stages of manufacturing the semiconductor device structure 100 taken along line A-A, line B-B, and line C-C of FIG. 6, respectively, in accordance with some embodiments. As shown in FIG. 8A, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layer 108, a dielectric layer is deposited in the cavities to form dielectric spacers 144. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

In some embodiments, instead of removing the edge portions of each second semiconductor layer 108, the second semiconductor layers 108 are removed and replaced with a dielectric material, such as high-density SiN or SiO. The edge portions of the dielectric material are removed, and the dielectric spacers 144 are formed to cap the dielectric material.

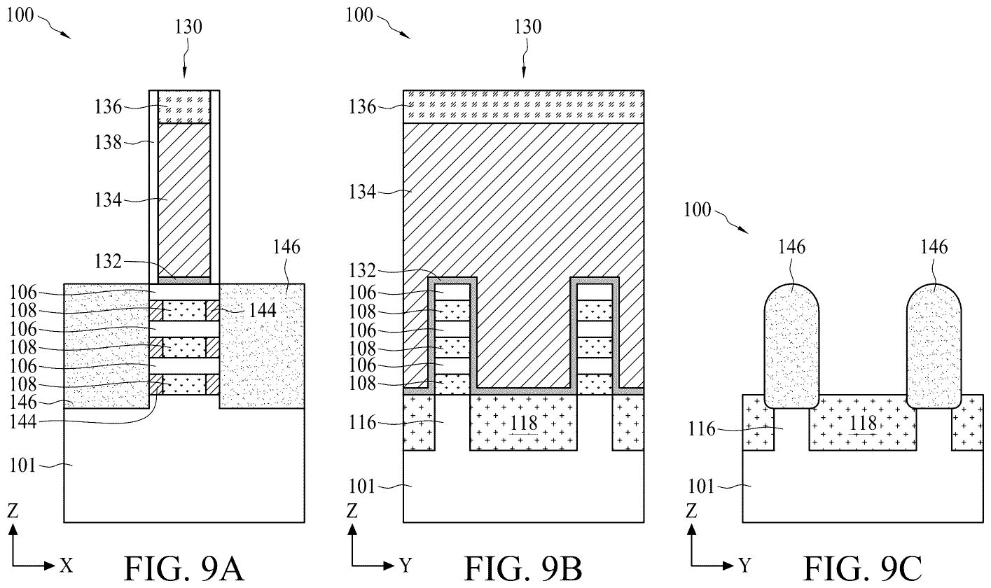

FIGS. 9A, 9B, and 9C are cross-sectional side views of one of various stages of manufacturing the semiconductor device structure 100 taken along line A-A, line B-B, and line C-C of FIG. 6, respectively, in accordance with some embodiments. As shown in FIGS. 9A and 9C, source/drain (S/D) regions 146 are formed from the substrate portions 116. In some embodiments, the S/D regions 146 may grow both vertically and horizontally to form facets, which may correspond to crystalline planes of the material used for the substrate portion 116. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or one or more layers of Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE.

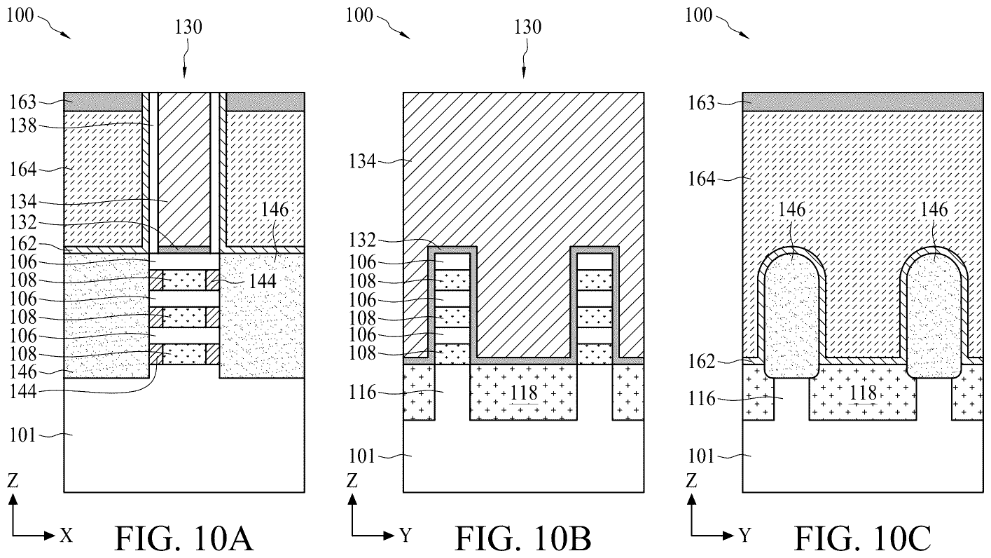

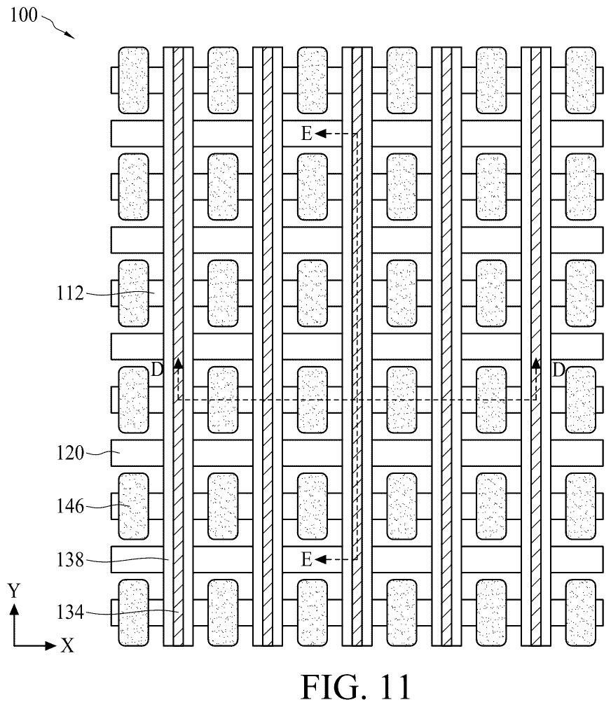

FIGS. 10A, 10B, and 10C are cross-sectional side views of one of various stages of manufacturing the semiconductor device structure 100 taken along line A-A, line B-B, and line C-C of FIG. 6, respectively, in accordance with some embodiments. In FIGS. 10A, 10B, and 10C, a contact etch stop layer (CESL) 162 is conformally formed on the exposed surfaces of the semiconductor device structure 100. The CESL 162 covers the sidewalls of the sacrificial gate structure 130, the insulating material 118, and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to cure the ILD layer 164.

After the ILD layer 164 is formed, a planarization operation, such as CMP, is performed on the semiconductor device structure 100 until the sacrificial gate electrode layer 134 is exposed, as shown in FIGS. 10A and 10B. In some embodiments, after the planarization process, the ILD layer 164 is recessed, and a dielectric layer 163 is formed on the recessed ILD layer 164. The dielectric layer 163 may include a nitride, such as silicon nitride, to protect the ILD layer 164 during subsequent processes. A second planarization process may be performed to remove portions of the dielectric layer 163 formed on the sacrificial gate electrode layer 134.

FIG. 11 is a top view of the semiconductor device structure 100 shown in FIGS. 10A, 10B, 10C, in accordance with some embodiments. Some components of the semiconductor device structure 100, such as the dielectric layer 163 and the CESL 162 are omitted in FIG. 11 for clarity. Furthermore, the locations of the S/D regions 146 and the isolation regions 120 are for illustration and are not exact. As shown in FIG. 11, the semiconductor device structure 100 includes S/D regions 146 formed on opposite sides of the sacrificial gate electrode layer 134. Each sacrificial gate electrode layer 134 has a longitudinal axis along the Y direction, while each fin structure 112 has the longitudinal axis along the X direction.

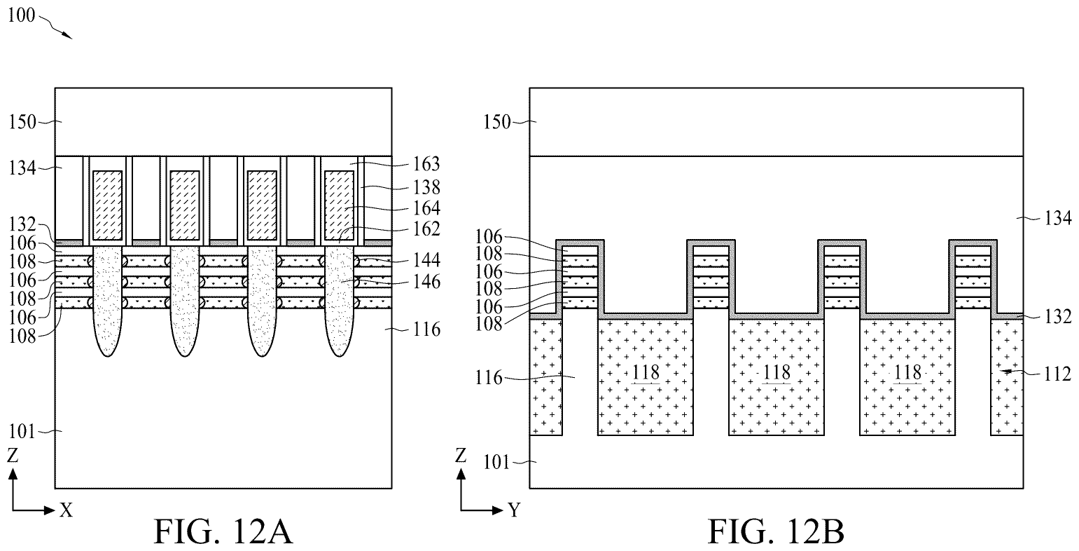

FIGS. 12A-16A are cross-sectional side views of various stages of manufacturing the semiconductor device structure 100 taken along line D-D of FIG. 11, in accordance with some embodiments. FIGS. 12B-16B are cross-sectional side views of various stages of manufacturing the semiconductor device structure 100 taken along line E-E of FIG. 11, in accordance with some embodiments. As shown in FIGS. 12A and 12B, a mask layer 150 is formed on the dielectric layer 163 and the sacrificial gate electrode layer 134. The mask layer 150 may include a dielectric layer, such as SiN, or a semiconductor material, such as amorphous Si.

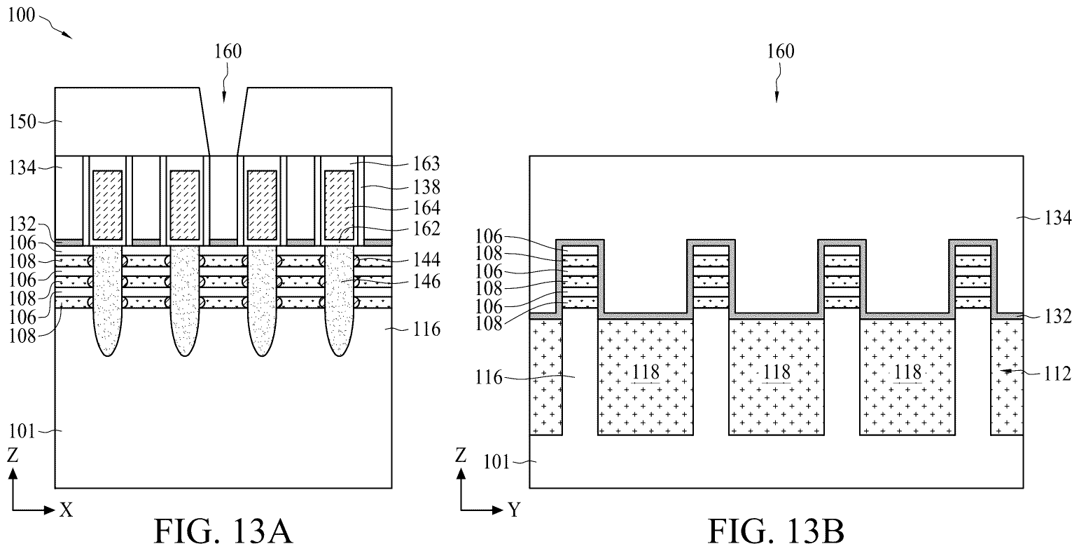

In FIGS. 13A and 13B, an opening 160 is formed in the mask layer 150. In some embodiments, the opening 160 exposes a portion of a sacrificial gate electrode layer 134, and the exposed portion of the sacrificial gate electrode layer 134 extends across multiple fin structures 112. In some embodiments, the exposed portion of the sacrificial gate electrode layer 134 extends four fin structures 112, as shown in FIG. 13B. Thus, the mask layer 150 is not shown in FIG. 13B.

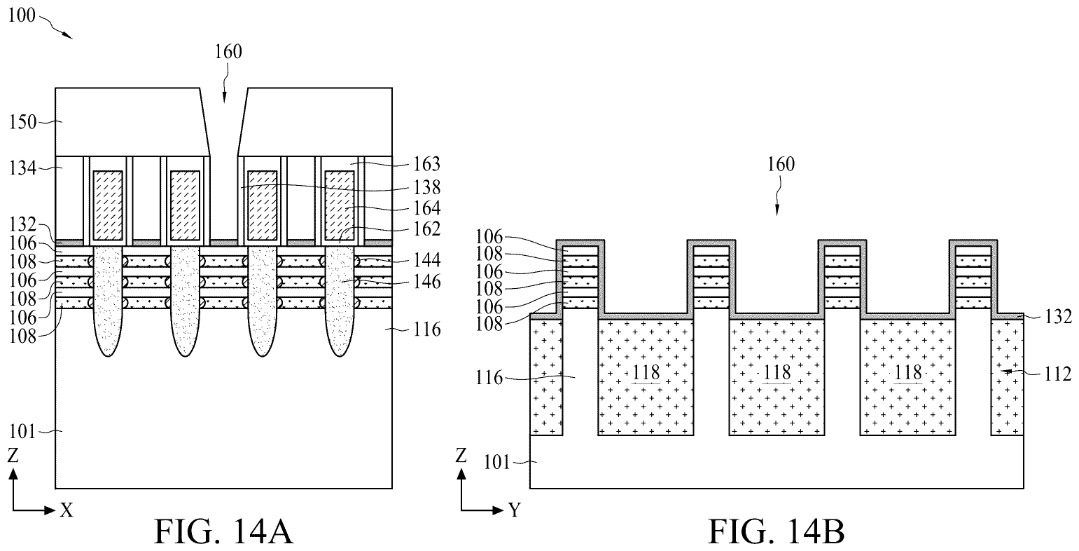

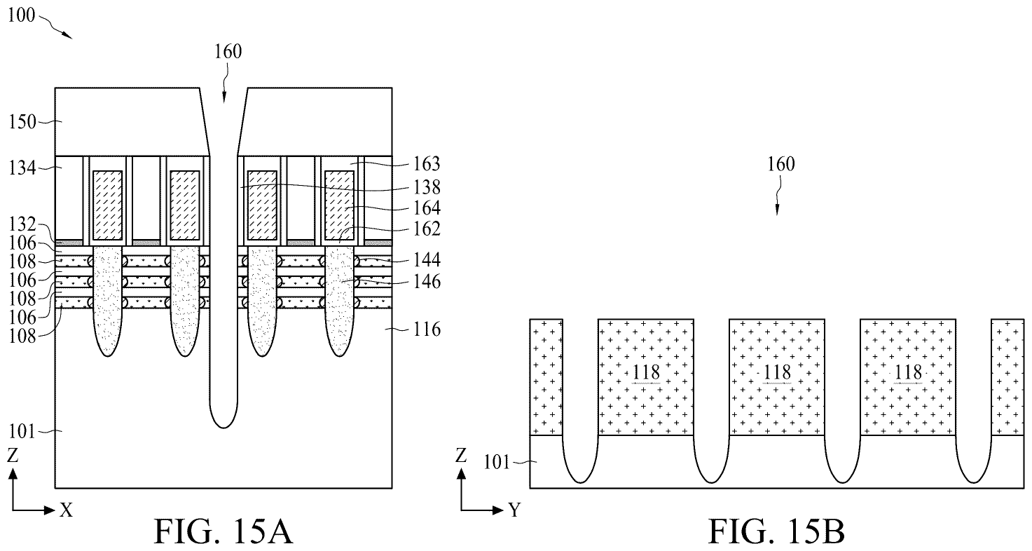

In FIGS. 14A and 14B, the exposed portion of the sacrificial gate electrode layer 134 is removed. The exposed portion of the sacrificial gate electrode layer 134 may be removed by an etch process, such as a selective etch process that does not substantially affect the mask layer 150 and the sacrificial gate dielectric layer 132. In FIGS. 15A and 15B, the exposed portion of the sacrificial gate dielectric layer 132 and the portions of the fin structures 112 located thereunder are removed. The portions of the fin structures 112 may be removed by one or more etch processes. In some embodiments, the one or more etch processes may be selective etch processes that do not substantially affect the dielectric materials of the mask layer 150, the dielectric spacers 144, and the insulating material 118. In some embodiments, the one or more etch processes may be anisotropic etch processes, and portions of the first semiconductor layers 106 under the gate spacers 138 and dielectric spacers 144 may remain, as shown in FIG. 15A. As shown in FIGS. 15A and 15B, the opening 160 extends into the substrate 101.

In some embodiments, the fin structure 112 includes the dielectric material instead of the second semiconductor layers 108, and the one or more etch process to remove the portions of the fin structures 112 may also recess the insulating material 118.

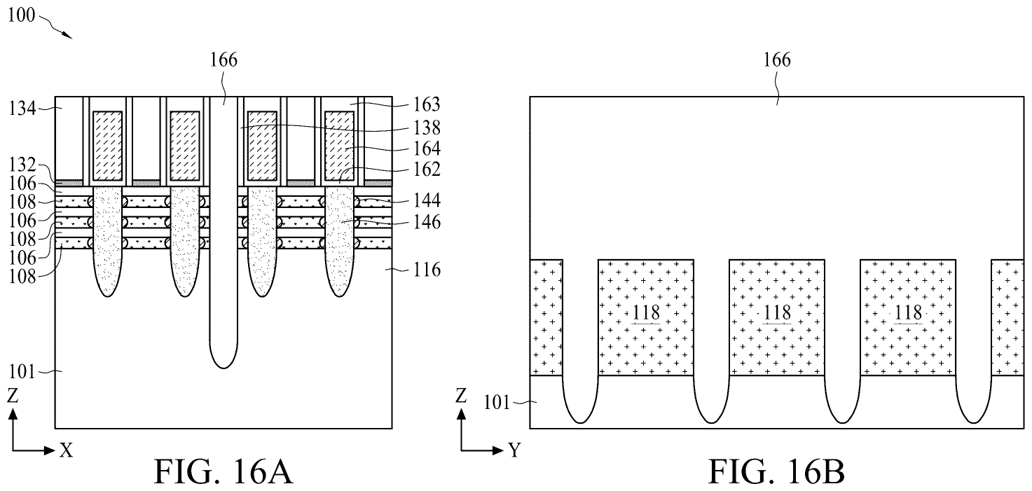

In FIGS. 16A and 16B, a dielectric material 166 is formed in the opening 160. The dielectric material 166 may include any suitable dielectric material. In some embodiments, the dielectric material 166 includes SiN. The dielectric material 166 may be also formed on the dielectric layer 163, and a planarization process, such as a CMP process, may be performed to remove portions of the dielectric material 166 formed on the dielectric layer 163. The CMP process may also remove the mask layer 150. In some embodiments, a liner (not shown) may be first deposited in the opening 160, and the dielectric material 166 is formed on the liner. The liner may be deposited by a conformal process, such as ALD. The liner and the dielectric material 166 may include different dielectric materials.

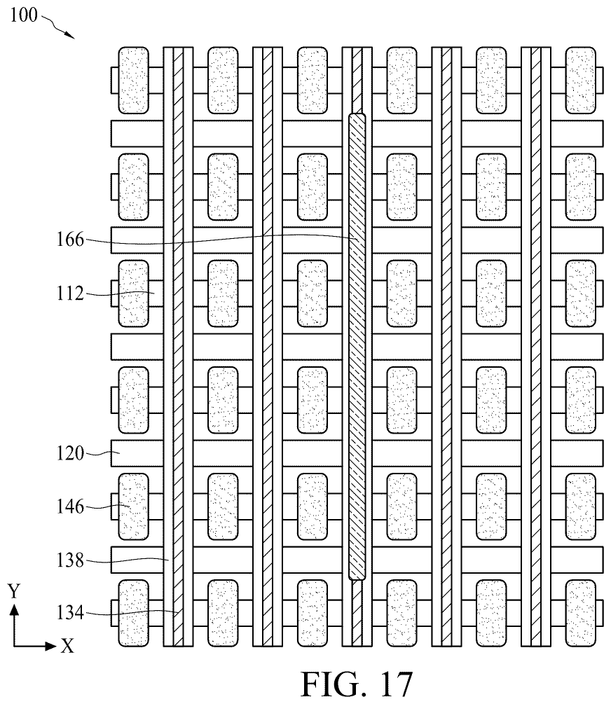

FIG. 17 is a top view of the semiconductor device structure 100 shown in FIGS. 16A and 16B, in accordance with some embodiments. Some components of the semiconductor device structure 100, such as the dielectric layer 163 and the CESL 162, are omitted in FIG. 17 for clarity. As shown in FIG. 17, a portion of the sacrificial gate electrode layer 134 is replaced by the dielectric material 166. The processes described in FIGS. 12A to 16B may be referred to as a continuous polysilicon on diffusion (CPODE) process, which is to divide active region into multiple segments or to isolate active devices. As shown in FIG. 17, in some embodiments, the dielectric material 166 has a longitudinal axis along the Y direction.

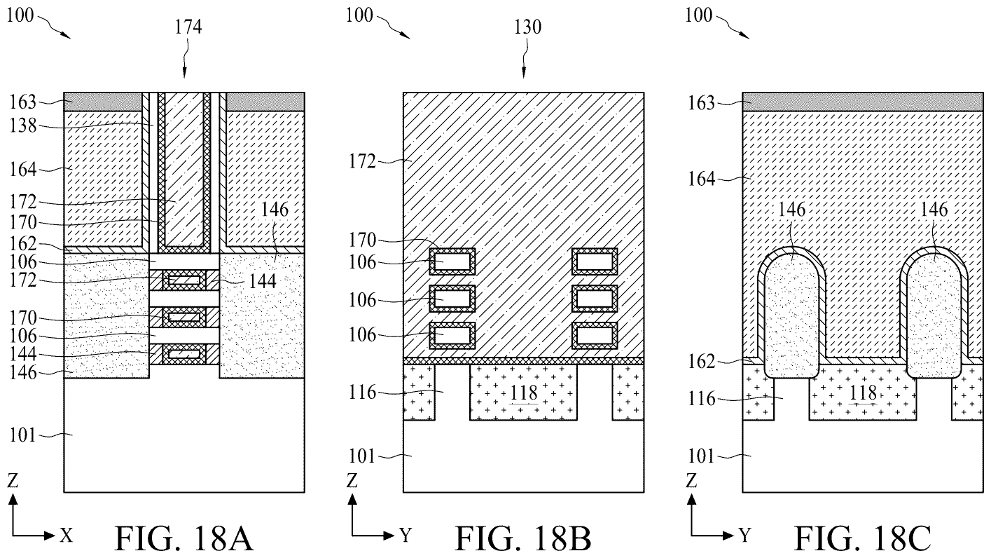

FIGS. 18A, 18B, 18C are various views of one of various stages of manufacturing the semiconductor device structure 100, in accordance with some embodiments. As shown in FIGS. 18A and 18B, the sacrificial gate structures 130 and the second semiconductor layers 108 are replaced with the gate dielectric layers 170 and the gate electrode layers 172. The removal of the sacrificial gate structure 130 and the semiconductor layers 108 forms an opening between gate spacers 138 and between first semiconductor layers 106. The dielectric materials of the dielectric layers 163 and the dielectric material 166 are not substantially affected by the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138, the dielectric material 166, the dielectric layer 163, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the gate spacers 138, the dielectric material 166, the dielectric layers 163, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

After the formation of the nanostructure channels (i.e., the exposed portions of the first semiconductor layers 106), the gate dielectric layer 170 is formed to surround the exposed portions of the first semiconductor layers 106, and the gate electrode layer 172 is formed on the gate dielectric layer 170. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the dielectric layers 163. The gate dielectric layer 170 and the gate electrode layer 172 formed over the dielectric layers 163 are then removed by using, for example, CMP, until the top surfaces of the dielectric layers 163 are exposed.

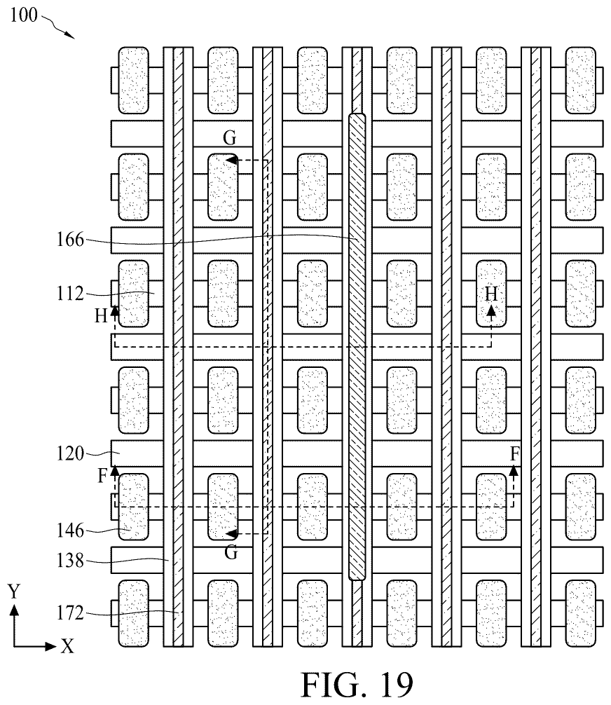

FIG. 19 is a top view of the semiconductor device structure 100 shown in FIGS. 18A, 18B, and 18C, in accordance with some embodiments. Some components of the semiconductor device structure 100, such as the dielectric layers 163, the gate dielectric layers 170, and the CESL 162, are omitted in FIG. 19 for clarity. As shown in FIG. 19, the sacrificial gate electrode layers 134 are replaced with the gate electrode layers 172.

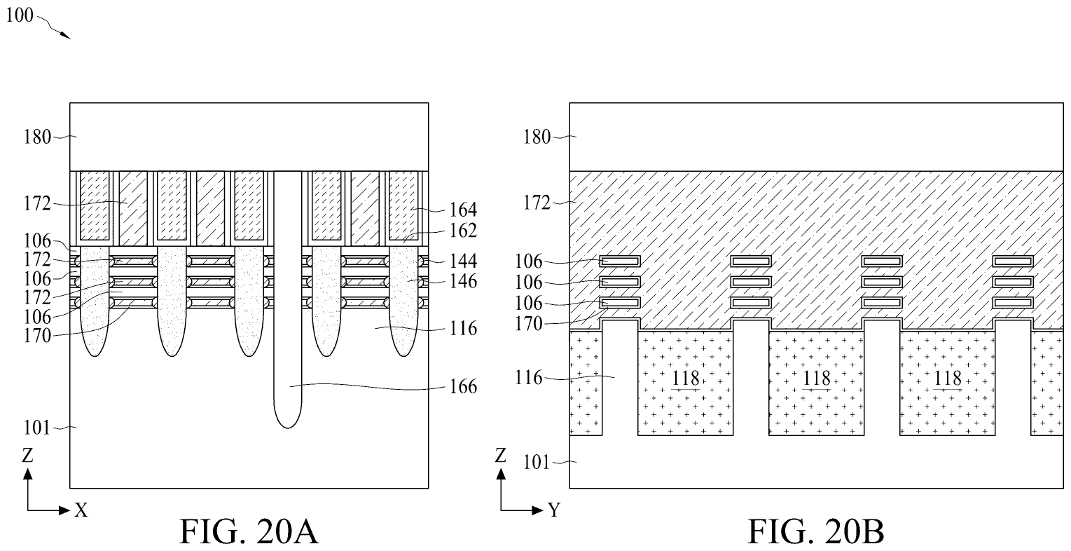

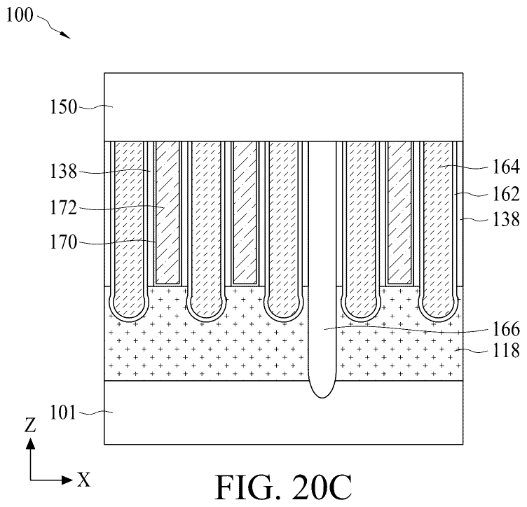

FIGS. 20A-24A are cross-sectional side views of various stages of manufacturing the semiconductor device structure 100 taken along line F-F of FIG. 19, in accordance with some embodiments. FIGS. 20B-24B are cross-sectional side views of various stages of manufacturing the semiconductor device structure 100 taken along line G-G of FIG. 19, in accordance with some embodiments. FIGS. 20C-24C are cross-sectional side views of various stages of manufacturing the semiconductor device structure 100 taken along line H-H of FIG. 19, in accordance with some embodiments. In some embodiments, the dielectric layers 163 are optional and are not formed on the recessed ILD layer 164. As shown in FIGS. 20A, 20B, 20C, a mask layer 180 is formed on the gate electrode layers 172, the ILD layer 164, and the dielectric material 166. The mask layer 180 may include the same material as the mask layer 150.

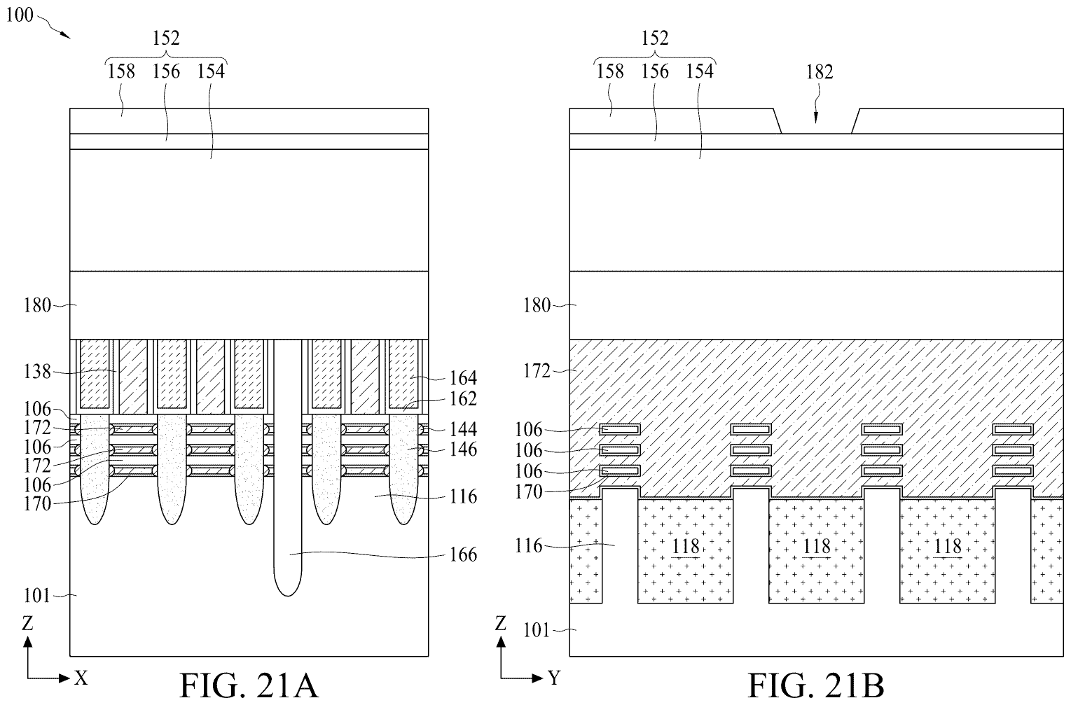

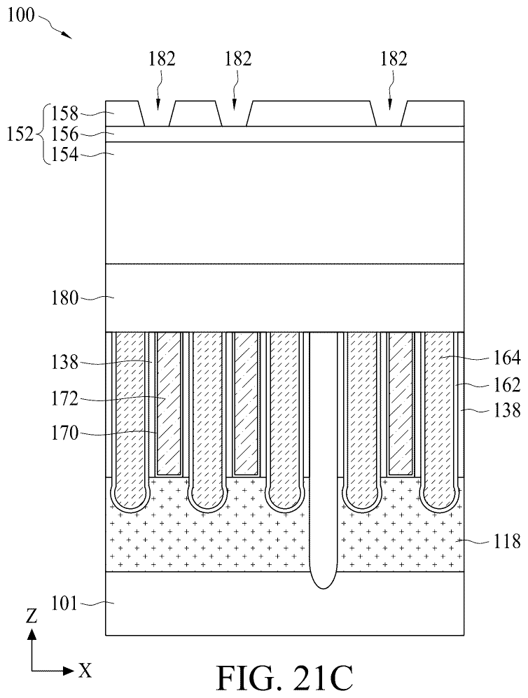

As shown in FIGS. 21A, 21B, 21C, a mask structure 152 is formed on the mask layer 180. In some embodiments, the mask structure 152 is a tri-layer photoresist. For example, the mask structure 152 may include a bottom layer 154 and a middle layer 156 disposed on the bottom layer 154. The bottom layer 154 and the middle layer 156 are made of different materials such that the optical properties and/or etching properties of the bottom layer 154 and the middle layer 156 are different from each other. In some embodiments, the bottom layer 154 may be a carbon layer, and the middle layer 156 may be a silicon-rich layer designed to provide an etch selectivity between the middle layer 156 and the bottom layer 154. The mask structure 152 further includes a photoresist layer 158 that may be a chemically amplified photoresist layer and can be a positive tone photoresist or a negative tone photoresist. The photoresist layer 158 may include a polymer, such as phenol formaldehyde resin, a poly (norbornene)-co-malaic anhydride (COMA) polymer, a poly(4-hydroxystyrene) (PHS) polymer, a phenol-formaldehyde (bakelite) polymer, a polyethylene (PE) polymer, a polypropylene (PP) polymer, a polycarbonate polymer, a polyester polymer, or an acrylate-based polymer, such as a poly (methyl methacrylate) (PMMA) polymer or poly (methacrylic acid) (PMAA). The photoresist layer 158 may be formed by spin-on coating. The photoresist layer 158 may be patterned to have openings 182 formed therein.

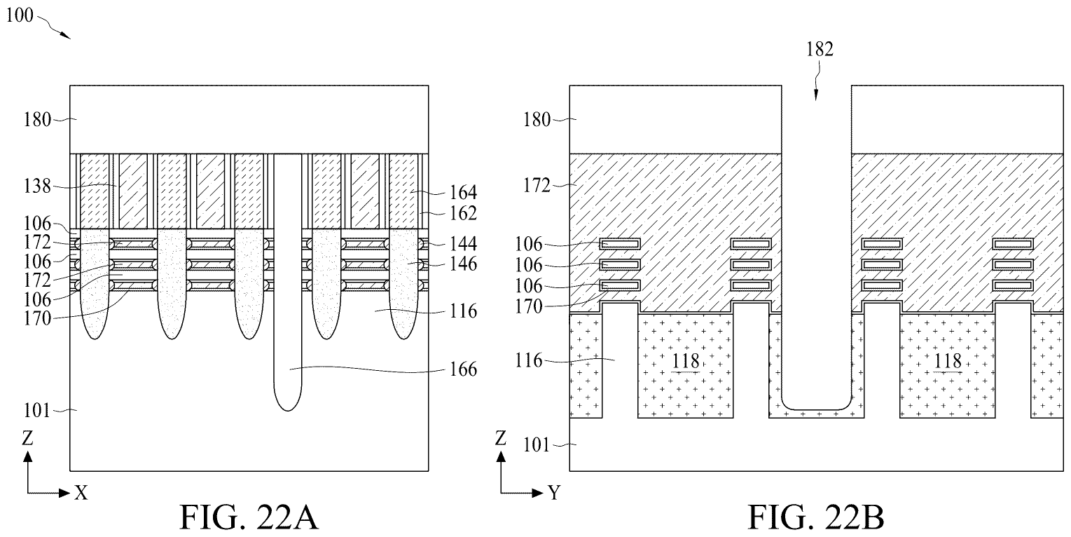

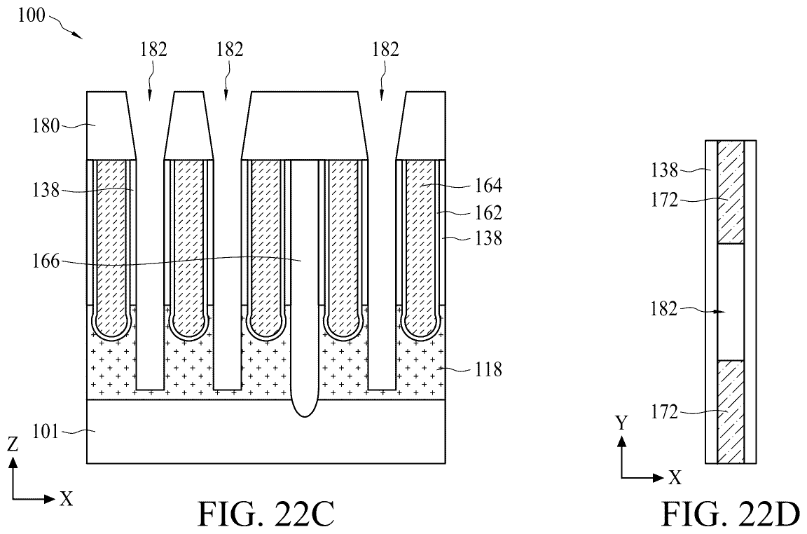

As shown in FIGS. 22A, 22B, 22C, the openings 182 are extended into the middle layer 156, the bottom layer 154, and the mask layer 180. The mask structure 152 may be removed after the openings 182 are extended into the mask layer 180. Portions of the gate electrode layers 172 and gate dielectric layers 170 are exposed in the openings 182. Next, the openings 182 are extended through the gate electrode layers 172 and the gate dielectric layer 170 by removing the exposed portions of the gate electrode layers 172 and the portions of the gate dielectric layer 170. In some embodiments, the openings 182 are extended into the insulating material 118, as shown in FIG. 22B and 22C. As shown in FIG. 22C, in some embodiments, the gate spacers 138 are protected by the mask layer 180 and are not removed during the removal of the portions of the gate electrode layers 172 and gate dielectric layer 170.

FIG. 22D is a top view of one of the openings 182, in accordance with some embodiments. The gate dielectric layer 170 is omitted for clarity in FIG. 22D. As shown in FIG. 22D, the opening 182 is formed between the gate spacers 138. In other words, the opening 182 does not extend through the gate spacers 138 along the X direction. In some embodiments, the opening 182 extends through the gate spacers 138 along the X direction. As a result, the opening 182 would be located between the S/D regions 146 (FIG. 19) located above and below the opening 182. With the subsequently formed dielectric material in the opening 182, the parasitic capacitance would be increased as a result of a dielectric material, which has a higher k value than that of the ILD layer 164, located between two conductive materials. Thus, by limiting the opening 182 between the gate spacers 138 along the X direction, parasitic capacitance is reduced.

As shown in FIG. 22D, the opening 182 is defined by the remaining portions of the gate electrode layer 172 along the Y direction. In some embodiments, if the opening 182 extends between two S/D regions 146 (FIG. 19) located along the X direction, parasitic capacitance may increase as a result of the subsequently formed dielectric material in the opening 182 being located between two conductive materials. Thus, the dimension of the opening 182 along the Y direction is less than or equal to the distance between two adjacent S/D regions 146 along the Y direction. However, if the opening 182 is too small, parasitic capacitance may also increase, because the subsequently formed dielectric material in the opening 182 is between two portions of the gate electrode layer 172. Thus, in some embodiments, the dimension of the opening 182 along the Y direction is about 80 percent to about 100 percent of the distance between two adjacent S/D regions 146 along the Y direction.

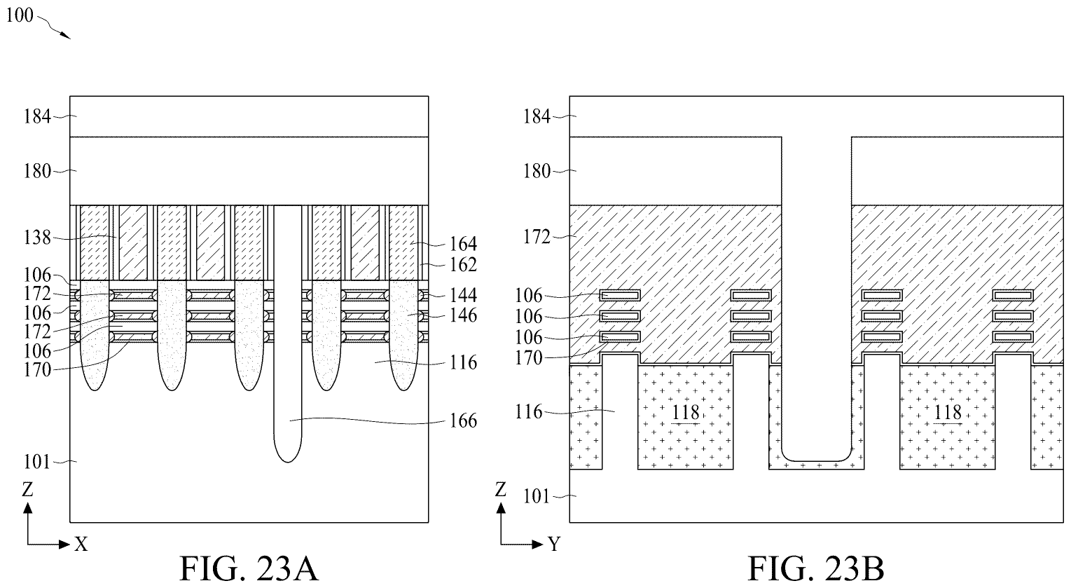

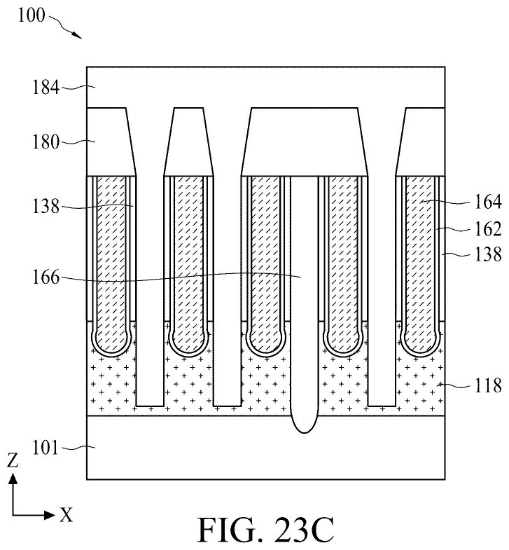

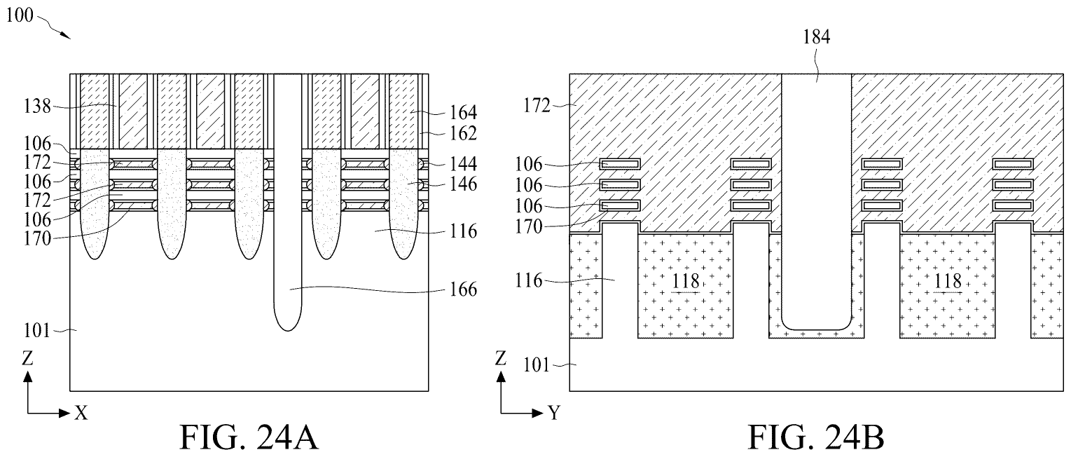

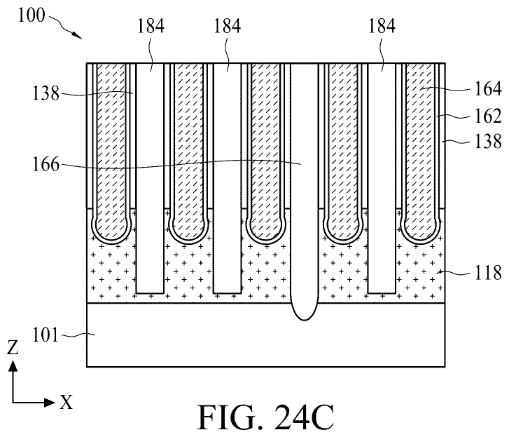

As shown in FIGS. 23A, 23B, 23C, a dielectric material 184 is deposited in the openings 182. The dielectric material 184 may include any suitable dielectric material. In some embodiments, the dielectric material 184 includes SiN or SiO. Next, a planarization process, such as a CMP process, may be performed to remove the portion of the dielectric material 184 deposited on the mask layer 180 and to remove the mask layer 180, as shown in FIGS. 24A, 24B, 24C. The processes described in FIGS. 20A to 24C may be referred to as a cut metal gate (CMG) process. The CMG process divides a gate electrode layer 172 into two or more portions, and the two or more portions may be controlled independently.

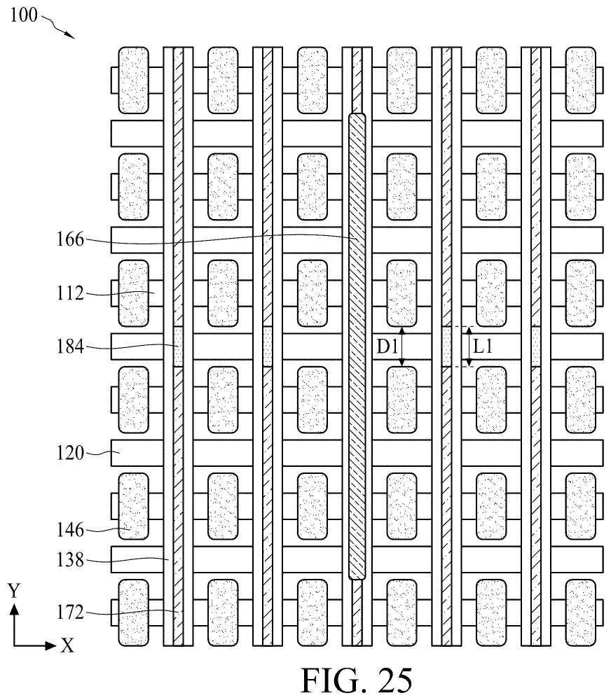

FIG. 25 is a top view of the semiconductor device structure 100 shown in FIGS. 24A, 24B, and 24C, in accordance with some embodiments. Some components of the semiconductor device structure 100, such as the dielectric layers 163, the gate dielectric layers 170, and the CESL 162, are omitted in FIG. 25 for clarity. As shown in FIG. 25, the dielectric materials 184 has a length L1 along the Y direction, and the length L1 is less than or equal to the distance D1 between adjacent S/D regions 146 along the Y direction. In some embodiments, the length L1 is about 80 percent to about 100 percent of the distance D1, in order to minimize parasitic capacitance. Furthermore, the dielectric material 184 is located between the gate spacers 138 and does not extend in the X direction between two adjacent S/D regions 146 along the Y direction to further reduce parasitic capacitance. In some embodiments, the dielectric material 184 has a longitudinal axis along the Y direction, and the longitudinal axis of the dielectric material 184 is substantially parallel to the longitudinal axis of the dielectric material 166, as shown in FIG. 25. The dielectric material 184 does not intersect the dielectric material 166.

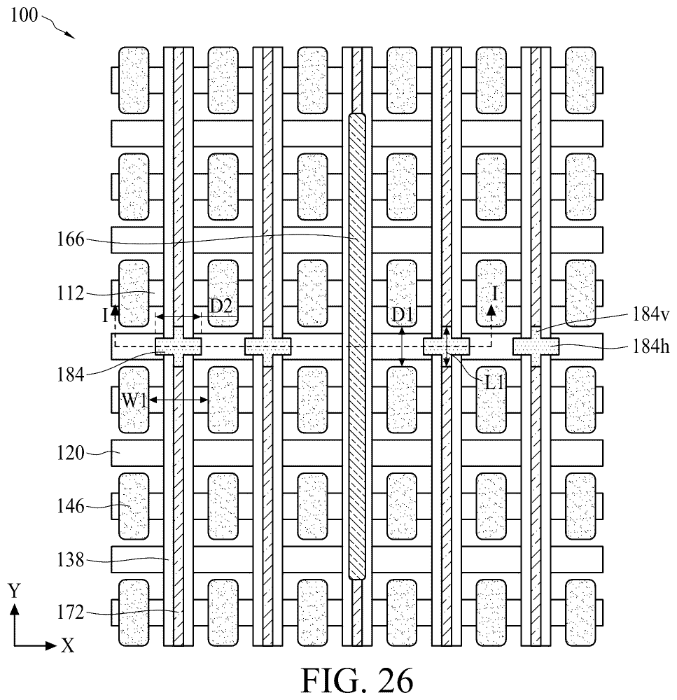

FIG. 26 is a top view of the semiconductor device structure 100, in accordance with alternative embodiments. Some components of the semiconductor device structure 100, such as the dielectric layers 163, the gate dielectric layers 170, and the CESL 162, are omitted in FIG. 26 for clarity. In some embodiments, misalignment may occur during the formation of the openings 182 (FIGS. 22B, 22C), and a portion of the gate electrode layer 172 may remain in the opening 182 (FIG. 22D). In other words, the mask layer 180 may cover a portion of the gate electrode layer 172, and there is not a complete cut in the gate electrode layer 172 to separate it into two or more portions. In some embodiments, the dielectric material 184 may have a cross shape, as shown in FIG. 26, in order to ensure a complete cut in the gate electrode layer 172. In other words, the top surface of the dielectric material 184 has a cross shape. In some embodiments, the dielectric material 184 includes a vertical portion 184v extending along the Y direction and a horizontal portion 184h extending along the X direction. The vertical portion 184v has the length L1, which is less than or equal to the distance D1 between adjacent S/D regions located along the Y direction. The horizontal portion 184h has a width W1, which is less than or equal to a distance D2 between adjacent S/D regions 146 located along the X direction. In some embodiments, the width W1 is about 80 percent to about 100 percent of the distance D2. In some embodiments, the S/D regions 146 are in contact with the gate spacers 138, and the distance D2 is the sum of the widths (along the X direction) of two gate spacers 138, two gate dielectric layers 170, and one gate electrode layer 172.

The width of the vertical portion 184v along the X direction is substantially less than the width W1, and the length of the horizontal portion 184h along the Y direction is substantially less than the length L1. Because the length L1 and the width L2 of the dielectric material 184 do not extend between conductive materials (i.e., adjacent S/D regions 146), parasitic capacitance is minimized. Furthermore, in case overlay (OVL) shift occurs due to misalignment during the formation of the openings 182, the opening for the horizontal portion 184h ensures that the gate electrode layer 172 are separated into two or more portions. The dielectric material 184 electrically isolates the two or more portions of the gate electrode layer 172. In some embodiments, the pattern of the photoresist layer 158 (FIGS. 21B, 21C) has the cross shape, and the pattern is transferred to the gate electrode layer 172.

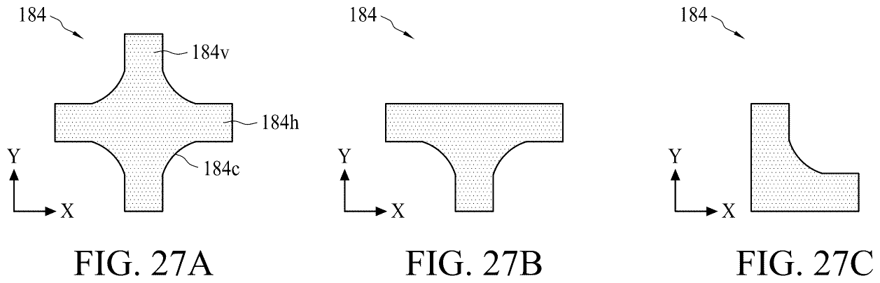

FIG. 27A-27C are top views of the dielectric material 184 of the semiconductor device structure 100 of FIG. 26, in accordance with some embodiments. As shown in FIG. 27A, in some embodiments, the dielectric material 184 includes the vertical portion 184v and the horizontal portion 184h. In some embodiments, a sharp corner is formed between the vertical portion 184v and the horizontal portion 184h, as shown in FIG. 26. In some embodiments, as shown in FIG. 27A, a connecting portion 184c having a curved surface connects the horizontal portion 184h and the vertical portion 184v. In some embodiments, the connecting portion 184c is concave.

In some embodiments, the horizontal portion 184h has a substantially constant length (along the Y direction), and the vertical portion 184v has a varying width (along the X direction). For example, the vertical portion 184v includes an upper portion located above the horizontal portion 184h and a lower portion located below the horizontal portion 184h. The upper portion of the vertical portion 184v has a width that increases in a direction towards the horizontal portion 184h, and the lower portion of the vertical portion 184v has a width that also increases in a direction towards the horizontal portion 184h. In some embodiments, the vertical portion 184v has a substantially constant width (along the X direction), and the horizontal portion 184h has a varying length (along the Y direction). For example, the horizontal portion 184h includes a left portion located on a first side of the vertical portion 184v and a right portion located on a second side opposite the first side of the vertical portion 184v. The left portion of the horizontal portion 184h has a length that increases in a direction towards the vertical portion 184v, and the right portion of the horizontal portion 184h has a length that also increases in a direction towards the vertical portion 184v.

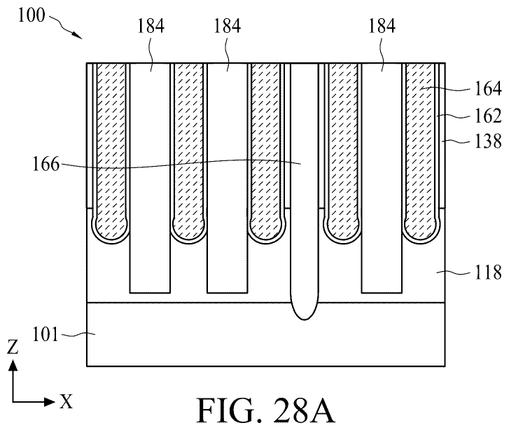

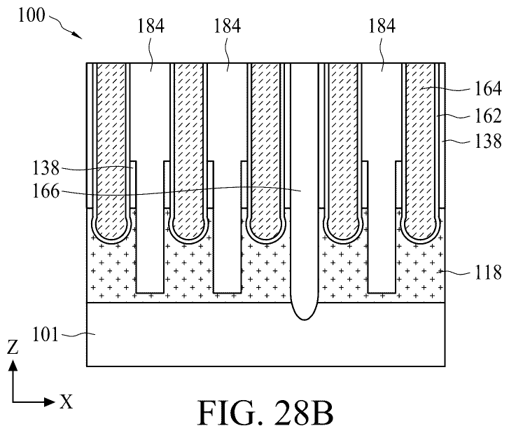

In some embodiments, the dielectric material 184 has a different shape. For example, near the edge of a functional circuit where the pattern type and density have drastic changes, the etch process to form the openings for the dielectric material 184 may have very different behavior than at other parts of the circuit with different pattern density. As a result, the dielectric material 184 may have a “T” shape, as shown in FIG. 27B, or a “L” shape, as shown in FIG. 28C.

FIGS. 28A and 28B are cross-sectional side views of one of various stages of manufacturing the semiconductor device structure 100 taken along line I-I of FIG. 26, in accordance with some embodiments. In some embodiments, as shown in FIG. 28A, the gate electrode layers 172, the gate dielectric layers 170, and the gate spacers 138 are removed when forming the openings 182, and the dielectric material 184 is in contact with the CESL 162. The removal of the gate electrode layers 172, the gate dielectric layers 170, and the gate spacers 138 may be performed by one or more etch processes that have low etch selectivity, so the materials of the gate electrode layers 172, the gate dielectric layers 170, and the gate spacers 138 are removed at the substantially the same rate. Alternatively, in some embodiments, the one or more etch processes have high etch selectivity. As a result, the gate electrode layers 172 and the gate dielectric layers 170 are removed, while the gate spacers 138 are recessed, as shown in FIG. 28B. As shown in FIG. 28B, the gate spacers 138 are recessed, and the dielectric material 184 is formed between and over the gate spacers 138. The dielectric material 184 includes a top portion having a first width along the X direction and a bottom portion having a second width along the X direction. In some embodiments, as a result of the existence of the recessed gate spacers 138, the first width is substantially greater than the second width.

As described above, in some embodiments, the dielectric material 184 is formed by a CMG process while the dielectric material 166 is formed by a CPODE process. Alternatively, the dielectric material 184 is formed by a cut poly (CPO) process, which is to form the openings 182 in the sacrificial gate electrode layers 134 to separate the sacrificial gate electrode layers 134 into multiple portions, forming the dielectric material 184 in the openings 182, and replacing the separated portions of the sacrificial gate electrode layers 134 with the gate electrode layers 172 and the gate dielectric layers 170. In some embodiments, the dielectric material 166 is formed by a continuous metal on-diffusion edge (CMODE) process, which is to form the opening 160 in the gate electrode layer 172 and the gate dielectric layer 170. The dielectric material 166 may be formed before or after the formation of the dielectric material 184. In some embodiments, the dielectric material 166 and the dielectric material 184 are formed at the same time. For example, the openings 160 and 182 may be formed at the same time using a single mask, and the openings 160 and 182 are filled with the dielectric materials 166, 184, respectively, at the same time.

In some embodiments, the semiconductor device structure 100 includes nanostructure transistors, as shown in the figures. In some embodiments, the semiconductor device structure 100 includes nanostructure transistors having hybrid fins located between fin structures 112. The hybrid fins may include one or more dielectric materials and are to isolate the S/D regions 146 and/or the gate electrode layers 172. The dielectric material 184 may be disposed on and/or around the hybrid fins, and the dielectric material 166 may be disposed around the hybrid fins. In some embodiments, the semiconductor device structures 100 includes FinFETs with or without hybrid fins.

Embodiments of the present disclosure provide a semiconductor device structure and methods of forming the same. In some embodiments, the semiconductor device structure includes a dielectric material 184 separating portions of the gate electrode layer 172. The dielectric material 184 has a length L1 that is less than or equal to the distance D1 between adjacent S/D regions 146 along the Y direction, and a width W1 that is less than or equal to the distance D2 between S/D regions 146 along the X direction. Some embodiments may achieve advantages. For example, by preventing the dielectric material 184, which has a higher k value than that of the ILD layer 164, from extending between adjacent S/D regions 146 (which can be conductive), parasitic capacitance is minimized.

An embodiment is a semiconductor device structure. The structure includes a first source/drain region, a second source/drain region disposed adjacent the first source/drain region along a first direction, a third source/drain region disposed adjacent the first source/drain region along a second direction substantially perpendicular to the first direction, a first gate electrode layer disposed between the first source/drain region and the third source/drain region, a second gate electrode layer disposed adjacent the second source/drain region, and a first dielectric material disposed between the first and second gate electrode layers. The first dielectric material has a length less than or equal to a first distance between the first and second source/drain regions.

Another embodiment is a semiconductor device structure. The structure includes a first source/drain region, a second source/drain region disposed adjacent the first source/drain region along a first direction, a third source/drain region disposed adjacent the first source/drain region along a second direction substantially perpendicular to the first direction, first and second gate spacers disposed between the first and third source/drain regions, and a first dielectric material disposed between the first and second gate spacers. A top surface of the first dielectric material has a cross shape.

A further embodiment is a method for forming a semiconductor device structure. The method includes forming first and second gate spacers over a substrate and forming first and second source/drain regions over the substrate. The first and second source/drain regions are aligned along a first direction and adjacent the first gate spacer. The method further includes forming a gate electrode layer between the first and second gate spacers and forming an opening in the gate electrode layer. The opening has a dimension along the first direction that is less than or equal to a distance between the first and second source/drain regions. The method further includes depositing a dielectric material in the opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a first source/drain region;
a second source/drain region disposed adjacent the first source/drain region along a first direction;
a third source/drain region disposed adjacent the first source/drain region along a second direction substantially perpendicular to the first direction;
a first gate electrode layer disposed between the first source/drain region and the third source/drain region;
a second gate electrode layer disposed adjacent the second source/drain region; and
a first dielectric material disposed between the first and second gate electrode layers, wherein the first dielectric material has a length less than or equal to a first distance between the first and second source/drain regions.

2. The semiconductor device structure of claim 1, further comprising first and second gate spacers, wherein the first and second gate electrode layers are disposed between the first and second gate spacers.

3. The semiconductor device structure of claim 2, wherein the first and second gate spacers are disposed between the first and third source/drain regions.

4. The semiconductor device structure of claim 2, wherein the first dielectric material is disposed between the first and second gate spacers.

5. The semiconductor device structure of claim 1, further comprising a second dielectric material disposed adjacent the third source/drain region, wherein the second dielectric material extends across first and second fin structures.

6. The semiconductor device structure of claim 5, wherein the first dielectric material is disposed between the first and second fin structures.

7. The semiconductor device structure of claim 1, wherein the first dielectric material has a width less than or equal to a second distance between the first and third source/drain regions.

8. A semiconductor device structure, comprising:
a first source/drain region;
a second source/drain region disposed adjacent the first source/drain region along a first direction;
a third source/drain region disposed adjacent the first source/drain region along a second direction substantially perpendicular to the first direction;
first and second gate spacers disposed between the first and third source/drain regions; and
a first dielectric material disposed between the first and second gate spacers, wherein a top surface of the first dielectric material has a cross shape.

9. The semiconductor device structure of claim 8, wherein the first dielectric material extends into the first and second gate spacers.

10. The semiconductor device structure of claim 8, wherein the first dielectric material comprises a horizontal portion and a vertical portion.

11. The semiconductor device structure of claim 10, wherein the first dielectric material further comprises a connecting portion connecting the horizontal portion and the vertical portion.

12. The semiconductor device structure of claim 11, wherein the connecting portion has a curved surface.

13. The semiconductor device structure of claim 8, further comprising a first gate electrode layer disposed between the first and second gate spacers and a second gate electrode layer disposed between the first and second gate spacers, wherein the first dielectric material is disposed between the first and second gate electrode layers.

14. The semiconductor device structure of claim 13, further comprising first and second fin structures.

15. The semiconductor device structure of claim 14, wherein the first dielectric material is disposed between the first and second fin structures.

16. The semiconductor device structure of claim 15, further comprising a second dielectric material disposed adjacent the third source/drain region, wherein the second dielectric material extends across the first and second fin structures.

17. A method for forming a semiconductor device structure, comprising:
forming first and second gate spacers over a substrate;
forming first and second source/drain regions over the substrate, wherein the first and second source/drain regions are aligned along a first direction and adjacent the first gate spacer;
forming a gate electrode layer between the first and second gate spacers;
forming an opening in the gate electrode layer, wherein the opening has a dimension along the first direction that is less than or equal to a distance between the first and second source/drain regions; and
depositing a dielectric material in the opening.

18. The method of claim 17, wherein the opening is formed between the first and second gate spacers.

19. The method of claim 17, wherein the opening extends into the first and second gate spacers.

20. The method of claim 17, wherein the opening has a cross shape when viewed from top.
